(19) United States
(12) Patent Application Publication
(10) Pub. No.: US 2021/0399082 A1
(43) Pub. Date: Dec. 23, 2021

(54) FLAT PANEL DISPLAY DEVICE HAVING REDUCED NON-DISPLAY REGION

(71) Applicant: Samsung Display Co., Ltd., Yongin-Si (KR)

(72) Inventors: Seung Hwan CHO, Yongin-si (KR); Seung Soo RYU, Yongin-si (KR); Joo Sun YOON, Yongin-si (KR); Dae Young JOUNG, Yongin-si (KR); Young Cheol JEONG, Yongin-si (KR); Jong Hyun CHOI, Yongin-si (KR)

(21) Appl. No.: 17/463,663

(22) Filed: Sep. 1, 2021

Related U.S. Application Data
(62) Division of application No. 16/282,043, filed on Feb. 21, 2019.

(30) Foreign Application Priority Data
Feb. 21, 2018 (KR) 10-2018-0020714

(51) Int. Cl. H01L 27/32; G02F 1/1362; G02F 1/1333; G09G 3/36; G09G 3/3225; H01L 51/00

(52) U.S. Cl. CPC H01L 27/3276; G02F 1/136286; G02F 1/133305; H01L 2251/5338; G09G 3/3225; H01L 51/0097; G09G 3/3648

(57) ABSTRACT

A flat panel display device includes: a substrate including a display region and a non-display region disposed at the periphery of the display region; a plurality of pixels disposed in the display region of the substrate, the plurality of pixels displaying an image; a plurality of pads disposed in the non-display region of the substrate; and a plurality of connecting lines electrically connecting the plurality of pads to the plurality of pixels. The plurality of pads are disposed above the plurality of connecting lines, and are electrically connected to the plurality of connecting lines through contact holes formed in an insulating layer. At least one pad among the plurality of pads overlaps with another connecting line connected to an adjacent pad.

### CROSS-REFERENCE TO RELATED APPLICATION

The present application is a divisional application of U.S. patent application Ser. No. 16/282,043 filed on Feb. 21, 2019, which claims priority under 35 USC § 119 to Korean patent application 10-2018-0020714 filed on Feb. 21, 2018, in the Korean Intellectual Property Office, the entire disclosures of which are incorporated herein in their entirety by reference.

### BACKGROUND

### 1. Technical Field

The present disclosure generally relates to a flat panel display device, and more particularly, to a flat panel display device capable of decreasing the size of a non-display region.

### 2. Related Art

A flat panel display device such as a liquid crystal display device (LCD) or an organic light emitting display device (OLED) has been widely used since it is thin and light.

Recently, attempts to decrease the size of the flat panel display device have been made according to requirements of users. On the other hand, users require high resolution, and hence there is required an improved structure capable of increasing resolution within a limited size.

The size of a non-display region should be decreased so as to decrease the size of the flat panel display device. However, as resolution increases, the density of lines in the non-display region increases. Hence, it is difficult to decrease the size of the non-display region.

### SUMMARY

Embodiments provide a flat panel display device capable of decreasing the size of a non-display region.

Embodiments also provide a flat panel display device having a decreased size.

According to an aspect of the present disclosure, there is provided a flat panel display device including: a substrate including a display region and a non-display region disposed at the periphery of the display region; a plurality of pixels disposed in the display region of the substrate, the plurality of pixels displaying an image; a plurality of pads disposed in the non-display region of the substrate; and a plurality of connecting lines electrically connecting the plurality of pads to the plurality of pixels, wherein the plurality of pads are disposed above the plurality of connecting lines, and are electrically connected to the plurality of connecting lines through contact holes formed in an insulating layer, and at least one pad among the plurality of pads overlaps with another connecting line connected to an adjacent pad.

The plurality of connecting lines may include: a plurality of scan lines arranged in a first direction and connected to respective pixels among the plurality of pixels; and a plurality of data lines arranged in a second direction intersecting the first direction and connected to respective pixels among the plurality of pixels. Each of the plurality of pixels may include: a light emitting device; and a thin film transistor connected to the light emitting device.

The plurality of pads may be disposed such that the central axis of each pad is vertical to one side of the substrate.

The another connecting line may extend to have a slope with respect to the central axis of the at least one pad. The slope may be smaller than 90 degrees.

The at least one pad may be disposed at both side portions of the plurality of pads.

The flat panel display device may further include a driving circuit electrically connected to the plurality of pixels and the pad. The driving circuit may be disposed in the non-display region of the substrate.

The flat panel display device may further include a driving circuit electrically connected to the plurality of pixels through the pad. The driving circuit may be provided by a flexible printed circuit board electrically connected to the pad.

According to another aspect of the present disclosure, there is provided a flat panel display device including: a substrate including a display region and a non-display region disposed at the periphery of the display region; a plurality of pixels disposed in the display region of the substrate, the plurality of pixels displaying an image; a plurality of pads disposed in the non-display region of the substrate; and a plurality of connecting lines electrically connecting the plurality of pads to the plurality of pixels, wherein the plurality of pads are disposed above the plurality of connecting lines, and are electrically connected to the plurality of connecting lines through contact holes formed in an insulating layer, and at least some pads among the plurality of pads are disposed such that their central axes are inclined at different angles with respect to one side of the substrate.

The plurality of connecting lines may be formed in one piece with a plurality of scan lines or electrodes of capacitors in the plurality of pixels.

The plurality of pads and a plurality of data lines may be formed using a same process.

The plurality of connecting lines may include: a plurality of scan lines arranged in a first direction and connected to respective pixels among the plurality of pixels; and a plurality of data lines arranged in a second direction intersecting the first direction and connected to respective pixels among the plurality of pixels. Each of the plurality of pixels may include: a light emitting device; and a thin film transistor connected to the light emitting device.

The plurality of pads may be disposed such that the central axis of each pad is parallel to the direction in which a corresponding connecting line extends.

The flat panel display device may further include a driving circuit electrically connected to the plurality of pixels and the pad. The driving circuit may be disposed in the non-display region of the substrate.

The flat panel display device may further include a driving circuit electrically connected to the plurality of pixels through the pad. The driving circuit may be provided by a flexible printed circuit board electrically connected to the pad.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a plan view of a flat panel display device according to an embodiment of the present disclosure.

FIG. 2 is a cross-sectional view illustrating a pixel shown in FIG. 1.

FIG. 3A is an enlarged plan view of portion X1 of FIG. 1.

FIG. 3B is a cross-sectional view taken along line A1-A2 of FIG. 3A.

FIG. 4A is an enlarged plan view of portion Y1 of FIG. 1.

FIG. 4B is a cross-sectional view taken along line B1-B2 of FIG. 4A.

FIGS. 5A, 5B and 5C are plan views of a flat panel display device according to another embodiment of the present disclosure.

FIG. 6A is an enlarged plan view of portion X2 of FIG. 5B.

FIG. 6B is an enlarged plan view of portion Y2 of FIG. 5B.

FIG. 6C is a cross-sectional view taken along line C1-C2 of FIG. 6B.

### DETAILED DESCRIPTION

Reference will now be made in detail to exemplary embodiments, examples of which are illustrated in the accompanying drawings, wherein like reference numerals refer to like elements throughout. In this regard, the present exemplary embodiments may have different forms and should not be construed as being limited to the descriptions set forth herein. Accordingly, the exemplary embodiments are merely described below, by referring to the figures, to explain aspects of the present description.

In the present disclosure, the terms “first”, “second” or the like are used only for the purpose of distinguishing one element from others, and therefore, the elements are not limited by the terms. As used herein, the singular forms are intended to include the plural forms as well, unless the context clearly indicates otherwise.

When an embodiment is implementable in another manner, a predetermined process order may be different from a described one. For example, two processes that are consecutively described may be substantially simultaneously performed or may be performed in an opposite order to the described order.

In the entire specification, when an element is referred to as being “connected” or “coupled” to another element, it can be directly connected or coupled to the another element or be indirectly connected or coupled to another element with one or more intervening elements interposed therebetween.

In addition, the size and thickness of each component illustrated in the drawings are arbitrarily shown for better understanding and ease of description, but the present disclosure is not limited thereto. Thicknesses of several portions and regions are exaggerated for clear expressions.

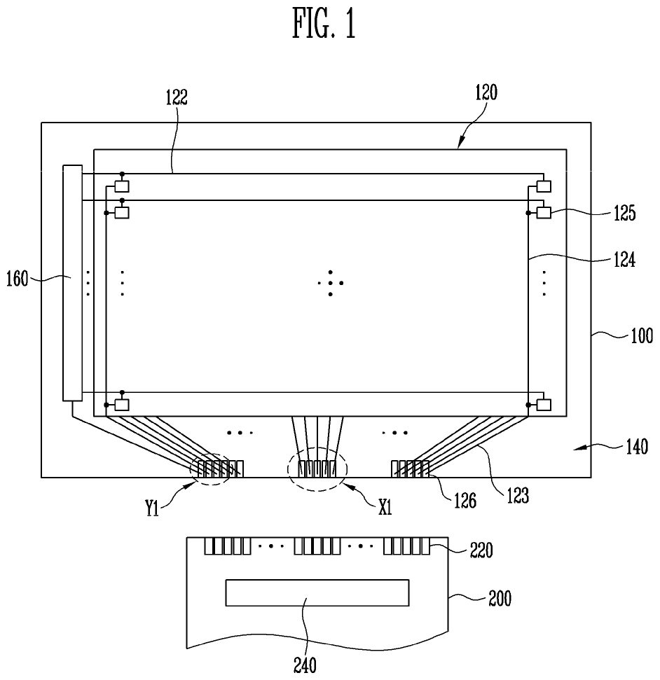

FIG. 1 is a plan view of a flat panel display device according to an embodiment of the present disclosure.

Referring to FIG. 1, the flat panel display device may be formed on a substrate 100.

The substrate 100 may be formed in a plate shape and be made of semiconductor, glass, quartz, metal, plastic, and the like. The substrate 100 may be a flexible substrate.

The substrate 100 may include a display region 120 and a non-display region 140 at the periphery of the display region 120.

A plurality of pixels 125 for displaying an image is disposed in the display region 120 of the substrate 100.

The plurality of pixels 125 may be connected to a plurality of scan lines 122 arranged in a first direction and a plurality of data lines 124 arranged in a second direction intersecting the first direction.

Each of the plurality of pixels 125 may include a light emitting device and a pixel circuit for driving the light emitting device. The pixel circuit may include a thin film transistor for transferring a signal to the light emitting device and a capacitor for maintaining the signal.

A plurality of pads 126 for receiving a signal from outside and a plurality of connecting lines 123 for electrically connecting the plurality of pads 126 to the plurality of pixels 125 are disposed in the non-display region 140 of the substrate 140.

The plurality of connecting lines 123 may include a line for transferring a signal and a line for supplying power.

The plurality of pads 126 may be disposed in the non-display region 140 adjacent to one side of the substrate 100 so as to receive a signal and power from the outside.

In addition, at least one driving circuit for driving the plurality of pixels 125 may be disposed in the non-display region 140 of the substrate 100. The driving circuit may be manufactured in the non-display region 140 of the substrate 100 in a process of manufacturing the plurality of pixels 125, or be manufactured as a separate semiconductor integrated circuit (IC) chip to be mounted in the non-display area 140 of the substrate 140.

In another embodiment, the at least one driving circuit may be provided at the outside of the flat panel display device, and be electrically connected to the plurality of pixels 125 through the pad 126.

Only a scan driver 160 is illustrated as the at least one driving circuit in FIG. 1. Input and output terminals of the scan driver 160 are electrically connected to the pad 126 and the scan line 122, respectively.

A data driver 240 may be provided in a separate flexible printed circuit board 200. A pad 220 of the flexible printed circuit board 200 is electrically connected to the pad 126 of the flat panel display device, so that the data driver 240 can be electrically connected to the data line 124 through the connecting line 123.

In still another embodiment, a data driver may be mounted between the plurality of pixels 125 and the plurality of pads 126. A middle portion of the connecting line 123 may be disconnected, and input and output terminals of the data driver may be connected to both of the disconnected ends of the connecting line 123, respectively.

The flat panel display device may include a controller (not shown). The controller may receive an image signal from the outside, generate a data signal, and provide the generated data signal to the data driver 240. Also, the controller may receive a synchronization signal and a clock signal from the outside, generate a control signal, and provide the generated control signal to the scan driver 160 and the data driver 240.

A light emitting device is selected by a scan signal provided through the scan line 122, and the amount of current flowing through the light emitting device is controlled according to a data signal provided through the data line 124, so that each of the plurality of pixels 125 can emit light with a predetermined luminance corresponding to the data signal.

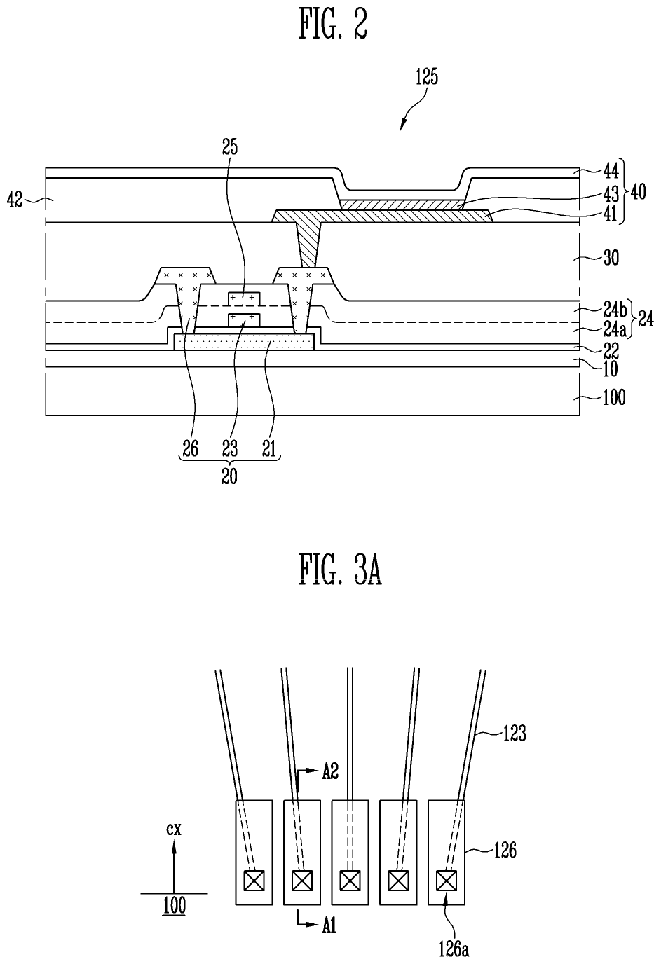

FIG. 2 is a cross-sectional view illustrating each of the plurality of pixels 125 shown in FIG. 1.

The each of the plurality of pixels 125 is formed in the display region 120 of the substrate 100.

A buffer layer 10 for preventing penetration of external air and planarizing a surface may be formed on the substrate 100, and a thin film transistor 20 may be formed on the buffer layer 10.

The thin film transistor 20 may include a semiconductor layer 21 that provides source and drain regions and a channel region, a gate electrode 23 that is disposed on the semiconductor layer 21 of the channel region and is electrically insulated from the semiconductor layer 21 by a gate insulating layer 22, and source and drain electrodes 26 electrically connected to the semiconductor layer 21 of the source and drain regions.

The source and drain electrodes 26 may be electrically connected to the semiconductor layer 21 of the source and drain regions through contact holes formed in an interlayer insulating layer 24.

The interlayer insulating layer 24 may include a first interlayer insulating layer 24a and a second interlayer insulating layer 24b disposed on the first interlayer insulating layer 24a.

A capacitor may include a capacitor electrode 25 disposed between the first interlayer insulating layer 24a and the second interlayer insulating layer 24b to overlap with the gate electrode 23.

A capacitance may be formed by the gate electrode 23, the first interlayer insulating layer 24a, and the capacitor electrode 25, which are disposed to overlap with each other.

A light emitting device 40 may be disposed on the substrate 100 including the thin film transistor 20 and the capacitor. The light emitting device 40 may include, for example, an organic light emitting diode (OLED).

A planarization layer 30 is formed on the substrate 100 including the thin film transistor 20 and the capacitor, and a first electrode 41 is formed, for example, as an anode electrode to be connected to the source or drain electrode 26 through a via hole formed in the planarization layer 30.

A pixel defining layer 42 is formed on the planarization layer 30 including the first electrode 41 such that the first electrode 41 of a light emission region is exposed, and an organic thin film layer 43 is formed on the exposed first electrode 41.

The organic thin film layer 43 may include a hole injection layer, a hole transport layer, an organic emitting layer, an electron transport layer, and an electron injection layer. The organic thin film layer 43 may further include an auxiliary layer or an intermediate layer.

A second electrode 44 is formed, for example, as a cathode electrode on the pixel defining layer 42 including the organic thin film layer 43.

In the embodiment, an organic light emitting display device is described as an example, but it will be apparent that the flat panel display device may be implemented with a liquid crystal display device.

Referring back to FIG. 1, the plurality of pads 126 may be disposed adjacent to the one side of the substrate 100, and each pad 126 may be disposed such that its central axis is vertical to the one side of the substrate 100.

Each pad 126 may be formed in rectangular shape including two short sides and two long sides. An axis that vertically passes through the two short sides opposite to each other may be defined as the central axis, or an axis in a direction extending in parallel to the two long sides opposite to each other may be defined as the central axis.

The plurality of pads 126 may be disposed above the plurality of connecting lines 123 to overlap with one longitudinal end portions of the plurality of connecting lines 123.

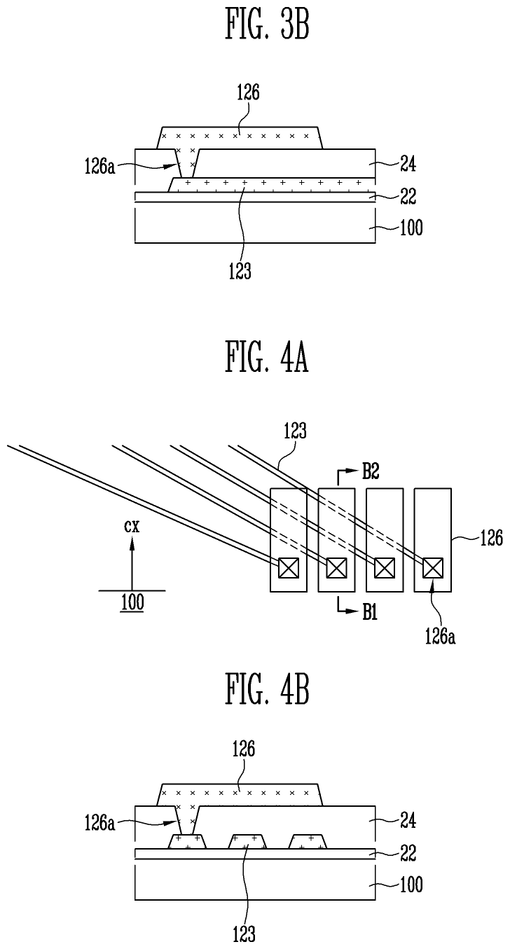

Referring to FIGS. 3A and 3B, for example, the plurality of connecting lines 123 may be formed on the gate insulating layer 22 on the non-display region 140 in a process of forming the gate electrode 23 of the thin film transistor 20, or be formed on the first interlayer insulating layer 24a on the non-display region 140 in a process of forming the capacitor electrode 25.

The plurality of pads 126 may be formed on the interlayer insulating layer 24 on the non-display region 140 in a process of forming the source and drain electrodes 26 of the thin film transistor 20.

The connecting line 123 and the pad 126 may be formed of at least one metal selected from the group consisting of Ag, Mg, Al, Pt, Pd, Au, Ni, Nd, Ir, Cr, Li, Ca, Mo, Ti, W, and Cu, or any alloy thereof.

FIG. 3A is an enlarged plan view of portion X1 of FIG. 1. FIG. 3B is a cross-sectional view taken along line A1-A2 of FIG. 3A.

The central axis CX of each of predetermined pads 126 located at a relatively central portion among the plurality of pads 126 may be almost parallel to the direction in which the connecting line 123 extends (see FIG. 3A).

The predetermined pads 126 are electrically connected to corresponding connecting lines 123 through contact holes 126a formed in the interlayer insulating layer 24, respectively (see FIG. 3B).

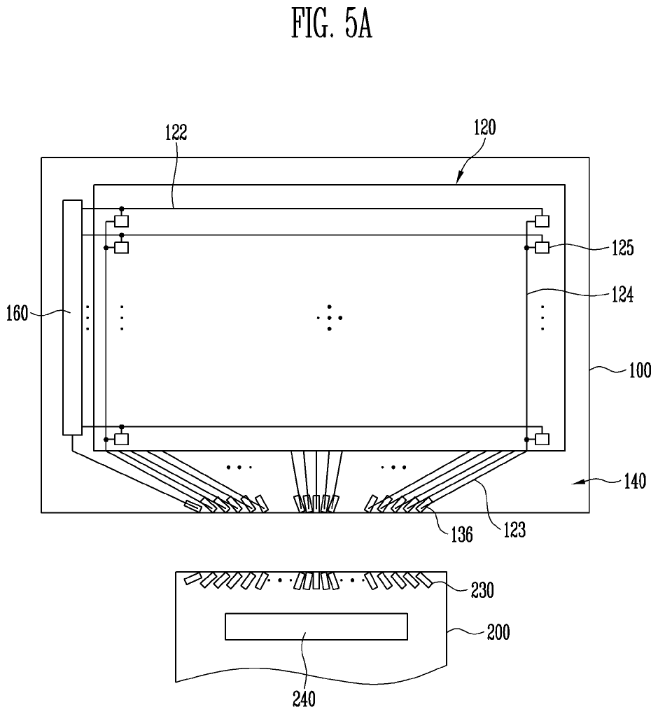

FIG. 4A is an enlarged plan view of portion Y1 of FIG. 1. FIG. 4B is a cross-sectional view taken along line B1-B2 of FIG. 4A.

The central axis CX of each of predetermined pads 126 located at both relatively side portions among the plurality of pads 126 may form a predetermined angle with the direction in which the connecting line 123 extends (see FIG. 4A).

The connecting line 123 extends to have a predetermined slope with which the connecting line 123 is inclined with respect to the central axis CX of the pad 126. Therefore, at least one pad 126 among the predetermined pads 126 may overlap with at least one connecting line 123 that is not connected to the at least one pad 126.

For example, the connecting line 123 may extend to have a slope smaller than 90 degrees with respect to the central axis CX of the pad 126, and the another connecting line 123 may be connected to another pad 126 adjacent to the at least one pad 126.

In an example, as shown in FIGS. 4A and 4B, one pad 126 (i.e., a left second pad) may overlap with two connecting lines 123 that are not connected thereto.

The predetermined pads 126 are electrically connected to corresponding connecting lines 123 through contact holes 126a formed in the interlayer insulating layer 24, respectively (see FIG. 4B).

In general, the plurality of pads 126 are disposed with an area narrower than that of the plurality of pixels 125.

When the central axis CX of each of the plurality of pads 126 is vertical to the one side of the substrate 100, the connecting line 123 extending from the plurality of pixels 125 may be bent at least once and then connected to the pad 126. The area required to bend the connecting line 123 is to be secured, and hence it is inevitable to increase the size of the non-display region 140.

However, in the embodiment of the present disclosure, the plurality of pads 126 are disposed to overlap with the plurality of connecting lines 123, so that the size of the non-display region 140 can be decreased by that of a pad unit.

Further, the connecting line 123 extending from the plurality of pixels 125 can be connected to the pad 126 in a state in which the connecting line 123 is not bent, and hence an increase in the size of the non-display region 140 can be prevented.

However, since the connecting line 123 extending from the plurality of pixels 125 is connected to the pad 126 in the state in which the connecting line 123 is not bent, at least one pad 126 disposed in the side portion may overlap with at least another connecting line 123 adjacent thereto as shown in FIGS. 4A and 4B. A parasitic capacitance is generated between the pad 126 and the connecting line 123 overlapping therewith, and therefore, a signal delay or a signal transfer failure may occur.

The thickness of the interlayer insulating layer 24 disposed between the pad 126 and the connecting line 123 is to be increased so as to decrease the parasitic capacitance.

In another embodiment of the present disclosure, there is provided a flat panel display device capable of minimizing or preventing the parasitic capacitance.

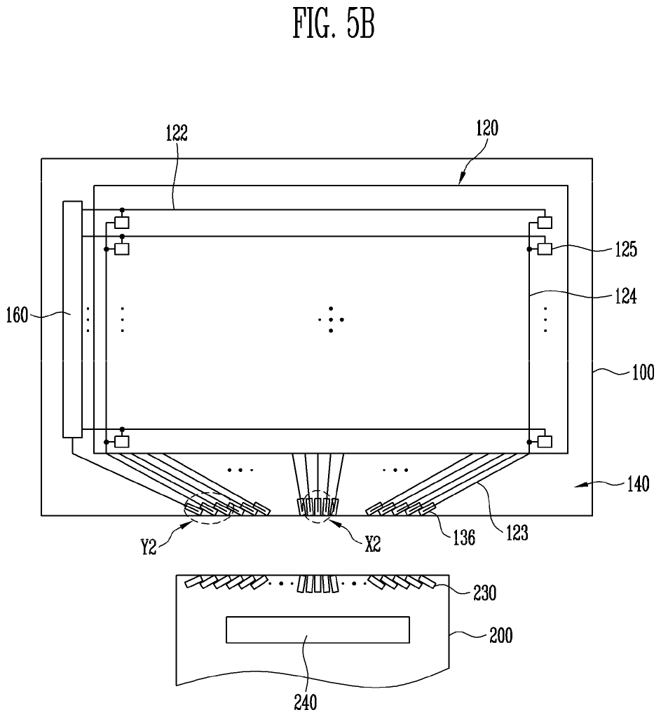

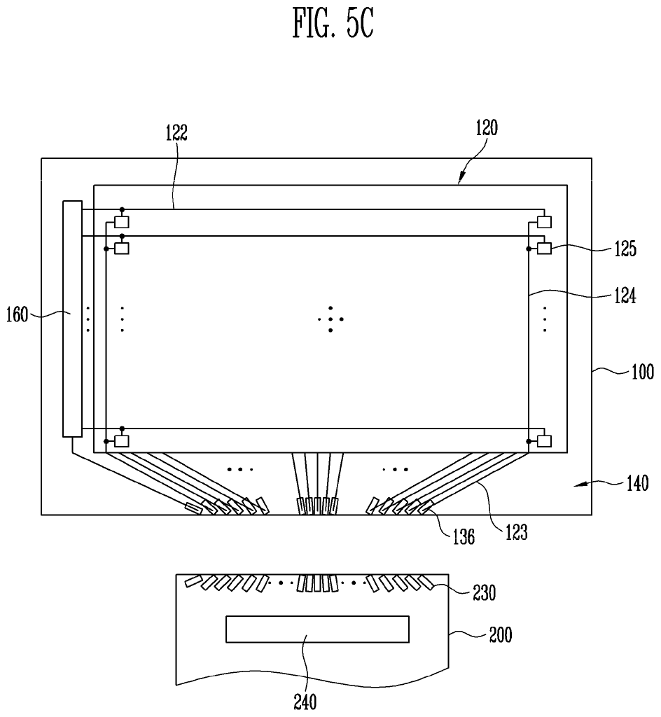

FIGS. 5A to 5C are plan views of a flat panel display device according to another embodiment of the present disclosure.

The flat panel display device of FIGS. 5A to 5C has a structure similar to that of the flat panel display device of FIG. 1, except the structure in which a plurality of pads 136 are disposed. Therefore, only portions different from those of FIG. 1 will be described.

Referring to FIG. 5A, the plurality of pads 136 may be disposed adjacent to one side of the substrate 100, and at least some pads 136 may be disposed such that their central axes are inclined at different angles with respect to the one side of the substrate 100.

A plurality of pads 230 of the flexible printed circuit board 200 including the data driver 240 is to have shapes respectively corresponding to the plurality of pads 136. The pad 230 of the flexible printed circuit board 200 is electrically connected to the pad 136 of the flat panel display device, so that the data driver 240 can be electrically connected to the data line 124 through the connecting line 123.

Since each of some pads 126 in the flat panel display device shown in FIG. 1 overlaps with at least another connecting line 123, an unwanted parasitic capacitance may be generated between the pad 126 and the connecting line 123 overlapping therewith.

However, when the pads 136 are disposed such that their central axes are inclined at different angles with respect to the one side of the substrate 100, the number of connecting lines 123 overlapping with each pad 136 may be decreased, and hence the generation of a parasitic capacitance can be minimized.

Referring to FIG. 5B, the plurality of pads 136 are disposed such that the central axis of each pad 136 is parallel to the direction in which each corresponding connecting line 123 extends, so that the generation of a parasitic capacitance can be prevented.

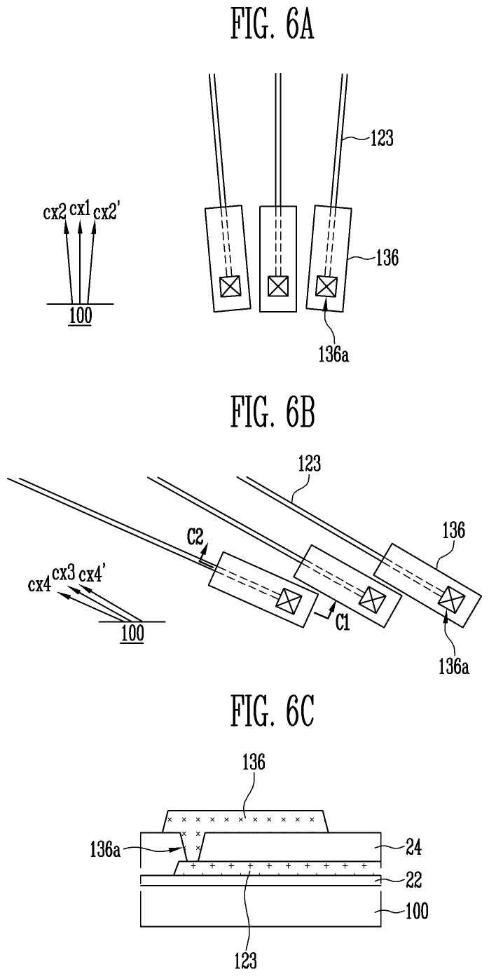

FIG. 6A is an enlarged plan view of portion X2 of FIG. 5B, and illustrates predetermined pads 136 located at a relatively central portion among the plurality of pads 136.

The predetermined pads 136 may be disposed such that their central axes CX1, CX2, and CX2′ are inclined at different angles with respect to the one side of the substrate 100.

In an example, each of the central axes CX1, CX2, and CX2′ of the predetermined pads 136 may be determined by the direction in which a corresponding connecting line 123 extends. Each of the predetermined pads 136 may be disposed such that its central axis CX1, CX2 or CX2′ is parallel to the direction in which the corresponding connecting line 123 extends.

The central axis CX1 of one pad 136 located at a central portion among the predetermined pads 136 may have, for example, a slope of about 90 degrees with respect to the one side of the substrate 100, and the central axes CX2 and CX2′ of both pads 136 adjacent to the one pad 136 may have a slope larger or smaller than 90 degrees.

FIG. 6B is an enlarged plan view of portion Y2 of FIG. 5B, and illustrates predetermined pads 136 located at both relatively side portions among the plurality of pads 136.

The predetermined pads 136 may be disposed such that their central axes CX3, CX4, and CX4′ are inclined at different angles with respect to the one side of the substrate 100.

In an example, each of the central axes CX3, CX4, and CX4′ of the predetermined pads 136 may be determined by the direction in which a corresponding connecting line 123 extends. Each of the predetermined pads 136 may be disposed such that its central axis CX3, CX4, and CX4′ is parallel to the direction in which the corresponding connecting line 123 extends.

For example, the central axis CX3 of one pad 136 located at a central portion among the predetermined pads 136 may be larger or smaller than 90 degrees with respect to the one side of the substrate 100, and the central axis CX3, CX4, and CX4′ may have different slopes.

FIG. 6C is a cross-sectional view taken along line C1-C2 of FIG. 6B. The plurality of pads 136 have the almost same sectional structure at the central portion and both the side portions.

Each pad 136 may be electrically connected to a corresponding connecting line 123 through a contact hole 136a formed in the interlayer insulating layer 24.

As shown in FIG. 6C, one pad 136 is disposed not to overlap with another connecting line 123, so that the generation of an unwanted parasitic capacitance can be effectively prevented.

FIG. 5C illustrates a structure obtained by combining the structure of the embodiment of FIG. 5A and the structure of the embodiment of FIG. 5B.

If necessary, some pads 136 may be disposed such that their central axes are inclined at different angles with the one side of the substrate 100, and some other pads 136 may be disposed such that the central axis of each pad 136 is parallel to the direction in which a corresponding connecting line 123 extends.

According to the present disclosure, a plurality of pads are disposed above a plurality of connecting lines. A separate area for forming the plurality of pads is not required, and hence the size of the non-display region can be decreased by that of the pad unit.

Further, according to the present disclosure, a plurality of pads are disposed such that the central axis of each pad is inclined at a predetermined angle with respect to one side of the substrate, so that the generation of a parasitic capacitance due to overlapping of the pad with the connecting line can be minimized. In particular, the plurality of pads are disposed such that the central axis of each pad is parallel to the direction in which a corresponding connecting line extends, so that the generation of a parasitic capacitance can be prevented.

The present disclosure can be usefully applied to a high-resolution flat panel display device in which the density of connecting lines in a non-display region is high.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A flat panel display device comprising:
a substrate including a display region and a non-display region disposed at the periphery of the display region;
a plurality of pixels disposed in the display region of the substrate, the plurality of pixels displaying an image;
a plurality of pads disposed in the non-display region of the substrate; and
a plurality of connecting lines electrically connecting the plurality of pads to the plurality of pixels,
wherein the plurality of pads are disposed above the plurality of connecting lines, and are electrically connected to the plurality of connecting lines through contact holes formed in an insulating layer, and
at least some pads among the plurality of pads are disposed such that their central axes are inclined at different angles with respect to one side of the substrate.

2. The flat panel display device of claim 1, wherein the plurality of connecting lines includes:
a plurality of scan lines arranged in a first direction and connected to respective pixels among the plurality of pixels; and
a plurality of data lines arranged in a second direction intersecting the first direction and connected to respective pixels among the plurality of pixels,
wherein each of the plurality of pixels includes:
a light emitting device; and
a thin film transistor connected to the light emitting device.

3. The flat panel display device of claim 1, wherein the plurality of pads are disposed such that the central axis of each pad is parallel to the direction in which a corresponding connecting line extends.

4. The flat panel display device of claim 1, further comprising a driving circuit electrically connected to the plurality of pixels and the pad,
wherein the driving circuit is disposed in the non-display region of the substrate.

5. The flat panel display device of claim 1, further comprising a driving circuit electrically connected to the plurality of pixels through the pad,
wherein the driving circuit is provided by a flexible printed circuit board electrically connected to the pad.

6. The flat panel display device of claim 1, at least one pad among the plurality of pads overlaps with another connecting line connected to an adjacent pad.

7. The flat panel display device of claim 6, wherein the plurality of connecting lines are formed in one piece with a plurality of scan lines or electrodes of capacitors in the plurality of pixels.

8. The flat panel display device of claim 7, wherein the plurality of pads and a plurality of data lines are formed using a same process.
